(19) United States
(12) Patent Application Publication
(10) Pub. No.: US 2024/0136449 A1
(43) Pub. Date: Apr. 25, 2024

(54) METALLIZATION FOR SILICON SOLAR CELLS

(71) Applicant: NEWSOUTH INNOVATIONS PTY LIMITED, Sydney, New South Wales (AU)

(72) Inventors: Brett Jason HALLAM, Sydney, New South Wales (AU); Catherine Emily CHAN, Sydney, New South Wales (AU); Daniel CHEN, Sydney, New South Wales (AU); Yuchao ZHANG, Sydney, New South Wales (AU); Brendan WRIGHT, Sydney, New South Wales (AU)

(21) Appl. No.: 18/278,256

(22) PCT Filed: Feb. 22, 2022
(86) PCT No.: PCT/AU2022/050132

§ 371 Date: Aug. 21, 2023

(30) Foreign Application Priority Data
Feb. 22, 2021 (AU) 2021900470

(51) Int. Cl. H01L 31/02; H01L 31/0224; H01L 31/18

(52) U.S. Cl. CPC H01L 31/0201; H01L 31/022433; H01L 31/1804

(57) ABSTRACT

A solar cell includes a semiconductor material having a dielectric layer over a light-receiving surface of the semiconductor material, a plurality of printed fire-through contacts passing substantially through the dielectric layer, each contact extending longitudinally in a first dimension, and a conductive finger extending longitudinally in a second dimension substantially perpendicular to the first dimension and electrically connecting the plurality of contacts to first and second busbars at opposite ends of the conductive finger. The conductive finger has at least one first portion overlaying and electrically connecting to the plurality of contacts, wherein each of the plurality of contacts extends beyond the first portion of the conductive finger at one or both sides of the first portion of the conductive finger in the first dimension, and wherein the first portion of the conductive finger overlays the dielectric.

### CROSS-REFERENCE TO RELATED APPLICATION

This application claims priority to Australian provisional patent application no. 2021900470, filed on 22 Feb. 2021, the entire content of which is incorporated herein by reference.

### TECHNICAL FIELD

The present disclosure relates to a solar cell having a metallization structure and a method of forming the solar cell.

### BACKGROUND

Solar cells are typically fabricated to include a semiconductor base/body, usually silicon, a passivating dielectric layer on or over the silicon, and a metallization structure. When light is absorbed in the semiconductor base, electrical charges are excited and move to the semiconductor surface where they can be extracted at the metallization structure for use in external circuits. The dielectric layer reduces recombination of charges at the semiconductor surface, thereby improving device efficiency.

To effectively extract charges from the solar cell, the metallization structure passes through the dielectric layer to contact the semiconductor underneath the dielectric layer, or to contact a conductive layer underneath the dielectric layer. The conductive layer may be located between the semiconductor and the dielectric layer, and may be a passivating layer (e.g. doped polysilicon) such as for screen-printed tunnel oxide passivated contact (TOPCon) solar cells. Where contact is with the semiconductor material it may be with a conductive region of the semiconductor material such as the emitter or p-type bulk for a screen-printed passivated rear emitter contact (PERC) solar cell.

Metal contacts of the metallization structure can be formed, for example, for PERC or TOPCon solar cells, by printing a ‘fire-through’ paste onto the surface of the dielectric layer in a desired electrode configuration. The paste comprises a metal component, along with other chemical components. When the printed paste is heated, it etches through the dielectric layer and consolidates into a solid metallization structure having a metal/silicon interface such as for PERC. For TOPCon solar cells, the metal may fire-through a dielectric layer to conduct a conductive passivating layer underneath such as doped polysilicon, without penetrating through the underlying tunnel oxide layer.

Screen-printed passivated rear emitter contact (PERC) solar cells and tunnel oxide passivated contact (TOPCon) solar cells are among the latest considered to be highly efficient industrial solar cells, achieving efficiencies above 23%, with PERC cells currently being the dominant technology. Other commercially available solar cells that are cheaper and easier to manufacture include conventional solar cells formed with screen-printed metallic contacts, despite commonly having lower efficiencies of around 20% due to a full area screen-printed aluminium back-surface field.

Metal structures at the surface of the solar cells may comprise a number of components, including metal fingers that pass through the dielectric layer and which are electrically connected, typically at either end, to metal busbars that carry the extracted charges to interconnection points such as conductive tabs.

Current screen-printed solar cells with metal fingers can suffer from low Voc values due to the relatively high metal-silicon interface area. With a finger width of approximately 40 micrometers and finger spacing of 1.3 mm, a metal-silicon interface area in the fingers alone can be 3%, and typically in the range of 2-4%. In addition, the front surface of PERC and TOPCon solar cells typically use high amounts of silver in the metal electrodes, significantly contributing to the cost of fabrication. Moreover, a significant amount of silver may be used for rear tabbing regions of PERC solar cells and silver contacts at the rear surface of TOPCon solar cells, greatly increasing the overall silver consumption.

Some attempts have been made to make smaller metal/silicon interface regions. One approach is to print narrower fingers or reduce finger height, although this is ultimately limited by the capability of the printing process and the need to ensure that the fingers are continuous to avoid yield losses. Printing narrower fingers also has the benefit of reducing shading and therefore increasing the short circuit current density. Another approach is a precise print-on-print process with intermittent finger regions for metal/silicon interface formation, followed by locating a metal finger over the finger regions (AIP Conference Proceedings 2147, 100001 (2019)). However, this is very challenging in the industrial environment due to stretching of the print screens causing a reduction in the preciseness of printing and therefore reducing yield. Moreover, to reduce silver consumption, alternative methods such as copper plating have been used, but this is a significant deviation from the current manufacturing process and brings added complexity of contact adhesion, interconnection and dealing with metallic wastes and high capital expenditure and ongoing costs for plating equipment. Copper based screen printing has also been proposed; however, contact at the silicon metal/interface with silver fingers is still required to avoid undesirable penetration of copper into the silicon. Screen-printed aluminium is another alternative for a p-type contact; however, this is unfavorable for an n-type contact due to the interaction between aluminium and silicon above the eutectic temperature of 577° C. This leaves a significant amounts of silver usage.

Any discussion of documents, acts, materials, devices, articles or the like which has been included in the present specification is not to be taken as an admission that any or all of these matters form part of the prior art base or were common general knowledge in the field relevant to the present disclosure as it existed before the priority date of each of the appended claims.

### SUMMARY

According to one aspect, the present disclosure provides a solar cell comprising:
a semiconductor material having a dielectric layer over a light-receiving surface of the semiconductor material;
a plurality of printed fire-through contacts passing substantially through the dielectric layer, each contact extending longitudinally in a first dimension; and
a conductive finger extending longitudinally in a second dimension substantially perpendicular to the first dimension and electrically connecting the plurality of contacts to first and second busbars at opposite ends of the conductive finger,
wherein the conductive finger has at least one first portion overlaying and electrically connecting to the plurality of contacts, wherein each of the plurality of contacts extends beyond the first portion of the conductive finger at one or both sides of the first portion of the conductive finger in the first dimension; and
wherein the first portion of the conductive finger overlays the dielectric layer and does not pass substantially through the dielectric layer.

According to another aspect, the present disclosure provides a method for fabricating a solar cell comprising:
depositing, on a dielectric layer that is over a light receiving surface of a semiconductor material, a fire-through paste to define a plurality of contacts passing substantially through the dielectric layer, each contact extending longitudinally in a first dimension; and
forming a conductive finger that extends longitudinally in a second dimension substantially perpendicular to the first dimension and electrically connects the plurality of contacts to first and second busbars at opposite ends of the conductive finger,
wherein forming the conductive finger comprises depositing non-fire-through paste to define at least a first portion of the conductive finger overlaying and electrically connecting to the plurality of contacts, wherein each of the plurality of contacts extends beyond the first portion of the conductive finger at one or both sides of the conductive finger in the first dimension; and
wherein the first portion of the conductive finger overlays the dielectric layer and does not pass substantially through the dielectric layer.

In some embodiments, each contact may extend beyond the first portion of the conductive finger by at least 5 micrometres, at least 10 micrometres, at least 15 micrometres, at least 20 micrometres, or at least 25 micrometres, at one or both sides of the first portion of the conductive finger in the first dimension, for example. Each contact may have a length in the first dimension of between about 30 and 500 micrometres, 30 and 400 micrometres, 30 and 300 micrometres, or 30 and 200 micrometres, for example. The first portion of the conductive finger may have a width in the first dimension of between about 10 and 100 micrometres, 20 and 80 micrometres, 20 and 60 micrometres, or 30 and 50 micrometres, for example. The first portion of the conductive finger may have a width in the first dimension that is less than about 90%, 80%, 70%, 60%, or 50%, of a length of each contact in the first dimension, for example. A spacing between adjacent contacts of the plurality of contacts along the length of the finger may be between about 60 and 500 micrometres, 100 and 400 micrometres, or 200 and 400 micrometres, for example. A thickness (height) of each contact may be less than 20 micrometres, less than 10 micrometres, between 5 and 10 micrometres, less than 5 micrometres, or otherwise.

In some embodiments, the first portion of the conductive finger overlaying the dielectric may be a non-fire-through portion of the conductive finger.

In some embodiments, the conductive finger may comprise at least one second portion, the second portion of the conductive finger passing substantially through the dielectric layer. The second portion of the conductive finger may be a printed fire-through portion of the conductive finger passing substantially through the dielectric layer.

Indeed, according to another aspect, the present disclosure provides a solar cell comprising:
a semiconductor material having a dielectric layer over a light-receiving surface of the semiconductor material;
a plurality of printed fire-through contacts passing substantially through the dielectric layer, and
a conductive finger electrically connecting the plurality of contacts to first and second busbars at opposite ends of the conductive finger,
wherein the conductive finger has at least one first portion overlaying and electrically connecting to the plurality of contacts, the at least one first portion overlaying and not passing substantially through the dielectric layer; and
wherein the conductive finger comprises at least one second portion, the second portion of the conductive finger being a printed fire-through portion of the conductive finger passing substantially through the dielectric layer.

According to another aspect, the present disclosure provides a method for fabricating a solar cell comprising:
depositing, on a dielectric layer that is over a light-receiving surface of a semiconductor material, a fire-through paste to define a plurality of contacts passing substantially through the dielectric layer; and
forming a conductive finger that electrically connects the plurality of contacts to first and second busbars at opposite ends of the conductive finger, wherein forming the conductive finger comprises:
depositing non-fire-through paste to define at least a first portion of the conductive finger overlaying and electrically connecting to the plurality of contacts, the at least one first portion overlaying and not passing substantially through the dielectric layer; and
depositing fire-through paste to define at least one second portion of the conductive finger that passes substantially through the dielectric layer.

In these aspects where the conductive finger comprises the different first and second portions, the contacts may be configured according to previous aspects such as to extend longitudinally in a direction that is substantially perpendicular to the longitudinal dimension of the conductive finger. However, alternatively, different configurations of the contacts may be used, including contacts that have longitudinal dimensions that are parallel with, or angled obliquely relative to, the longitudinal dimension of the conductive finger, and which may or may not extend beyond the first portion of the conductive finger at one or both sides of the conductive finger in the first dimension.

In any of the aspects above, the plurality of printed contacts and/or the second portion of the conductive finger may directly contact the semiconductor or may contact a conductive layer that may be located between the semiconductor material and the dielectric layer in some solar cells, such as a polysilicon layer or a variety of passivated contacts including metal oxide layers.

In some embodiments, the second portion of the conductive finger may not overlay any of the plurality of contacts. In some embodiments, the second portion of the conductive finger may overlay no more than one or two of the plurality of contacts. In some embodiments, the second portion of the conductive finger may overlay no more than 10% of the total number of the plurality of contacts.

In some embodiments, the second portion of the conductive finger may comprise two second portions of the conductive finger, the two second portions of the conductive finger located at opposite ends of the first portion of the conductive finger and optionally located proximal to the first and second bus bars, respectively. Alternatively, in some embodiments, the first portion of the conductive finger may comprise two first portions of the conductive finger, the two first portions of the conductive finger located at opposite ends of the second portion of the conductive finger and optionally located proximate to the first and second bus bars, respectively

In some embodiments, the conductive finger may have a higher conductivity at portions or regions of the conductive finger proximate the first and second bus bars, respectively, than at a central region between the first and second bus bars. Depending on the positioning of the first and second portions, in some embodiments the second portion of the conductive finger may therefore have a higher conductivity than the first portion of the conductive finger, whereas in other embodiments the first portion of the conductive finger may have a higher conductivity than the second portion of the conductive finger. Any portion of the conductive finger may have a higher conductivity than another portion of the conductive finger by comprising higher conductivity material than the other portion of the conductive finger and/or by having a different geometry, such as greater material thickness or width than the other portion of the conductive finger, for example

In some embodiments, the first and/or second busbar may be connected to at least one interconnection point (e.g. conductive tab). The at least one interconnection point may be formed in the same or a different manner as the plurality of contacts, the first and second busbars, the first portion of the conductive finger, and/or the second portion of the conductive finger. The at least one interconnection point may be a printed fire-through interconnection point that passes substantially through the dielectric layer, for example. In some embodiments, each busbar may be connected to interconnection points located at points along the busbar, for example.

In some embodiments, one or more of the busbars may have a higher conductivity at portions or regions of the busbar proximate one or more interconnection points than at a central region between interconnection points. Any portion of a busbar may have a higher conductivity than another portion of the busbar by comprising higher conductivity material than the other portion of the busbar and/or by having a different geometry, such as greater material thickness or width than the other portion of the busbar, for example.

In some embodiments, the plurality of contacts, the first portion of the conductive finger, the second portion of the conductive finger (when present), the first and second busbars, and the interconnection points (when present) may be provided at a light-receiving surface of the solar cell such as the front/main light-receiving surface of the solar cell or a rear light-receiving surface of the solar cell (e.g., in the case of a TOPCon n-type contact).

In some embodiments, the plurality of contacts, the first portion of the conductive finger, the second portion of the conductive finger (when present), the first and second busbars, and the interconnection point (when present) may each be formed of metallic material, wherein the metallic material may be a pure form of metal or a combination (e.g. alloy) of metals.

In some embodiments, the plurality of contacts are formed of a first metallic material and at least the first portion of the conductive finger is formed of a second metallic material, the second metallic material being different from the first metallic material. The first metallic material may be silver (e.g. pure silver, or a silver alloy or other combination of materials with greater than 70%, greater than 80%, greater than 90% or greater than 95% wt % of silver), for example. The second metallic material may be a metal, or a metal alloy, that does not include silver, or that has a reduced level of silver such as less than 70%, less than 50% or less than 30% wt % of silver, for example. Material with a reduced level of silver may comprise silver and any one or more of aluminium, copper and tin, for example, or otherwise. For example, the first portion of the conductive finger may be formed of aluminium, copper, silver coated copper, tin, tin alloy or silver/aluminium alloy. The second portion of the conductive finger when present may be formed of silver, aluminium, copper, tin, tin alloy or silver/aluminium alloy, for example. The interconnection point when present may be formed of silver, aluminium, copper, tin, tin alloy or silver/aluminium alloy, for example. Tin alloys according to the present disclosure may include lead or lead-free solders such as tin-silver-copper solders, tin-silver or otherwise and, in general, tin or tin alloys can be readily solderable and reduce the risks of shunt losses, for example. Depending on selected composition by wt % of tin and silver, a tin-silver alloy may advantageously be selected to have a melting temperature of anywhere between about 200 to 800 C, for example.

In some embodiments, when the solar cell comprises:
(i) the plurality of contacts,
(ii) the first portion of the conductive finger,
(iii) the first and second busbars, and optionally
(iv) the second portion of the conductive finger, and
(v) the interconnection point,
   any two or more of the items (i) to (v) are formed of a first metallic material and the remaining items of items (i) to (v) are formed of a second metallic material, the second metallic material being different from the first metallic material.

Following from this, a metallization structure that comprises the plurality of contacts, the first portion of the conductive finger, the second portion of the conductive finger (when present), the first and second busbars, and interconnection point (when present), may be formed from a two-step printing process, the first and second metallic materials used to form the respective items being printed by respective first and second printing steps.

Nevertheless, in some embodiments, three different metallic materials may be used for the metallization structure, whereupon the metallization structure may be formed from first, second and third printing steps.

Merely as examples: in some embodiments the plurality of contacts and the at least one interconnection point and/or first and second busbars may be formed of the first metallic material and the at least one first portion of the conductive finger may be formed of the second metallic material. In some embodiments, the plurality of contacts may be formed of the first metallic material and the at least one first portion of the conductive finger and the at least one interconnection point and/or first and second busbars may be formed of the second metallic material. In some embodiments, the plurality of contacts, the at least one second portion of the conductive finger, and the at least one interconnection point and/or first and second busbars may be formed of the first metallic material and the at least one first portion of the conductive finger may be formed of the second metallic material. In some embodiments, the plurality of contacts, the at least one second portion of the conductive finger and the at least one interconnection point and/or first and second busbars may be formed of the same metallic material. In some embodiments, the first portion of the conductive finger and the one or more interconnection points and/or first and second busbars may be formed of the same metallic material.

In some embodiments, a metal/semiconductor material interface area (e.g. metal/silicon interface area) of the solar cell, at the light-receiving surface of the semiconductor material, is between 0.5% and 2%, or 1% and 2%, or 0.5% and 1.5%, of the total area of the light-receiving surface of the semiconductor material. The interface area may correspond to the area at which direct contact is made between metallisation, such as the fired-through plurality of contacts, and (i) the semiconductor material, or (ii) the conductive layer that may be located between the semiconductor material and the dielectric layer in some solar cells.

In some embodiments, solar cells may be provided that are configured according to solar cells as discussed above, although not necessarily using a fire-through printing step to form the plurality of contacts or second portion of the conductive finger, for example.

### BRIEF DESCRIPTION OF DRAWINGS

By way of non-limiting example, embodiments of the present disclosure are now described with reference to the accompanying Figures in which:

FIG. 1 show a schematic plan view of a portion of a solar cell according to an embodiment of the present disclosure;

FIG. 2 shows a schematic cross-sectional view of the portion of the solar cell of FIG. 1 along line A--A of FIG. 1;

FIG. 3 show a schematic plan view of a portion of a solar cell according to another embodiment of the present disclosure;

FIG. 4 show a schematic plan view of a portion of a solar cell according to another embodiment of the present disclosure;

FIG. 5 shows a schematic cross-sectional view of the portion of the solar cell of FIG. 4 along line A--A of FIG. 4;

FIG. 6 show a schematic plan view of a portion of a solar cell according to another embodiment of the present disclosure;

FIG. 7 show a schematic plan view of a portion of a solar cell according to another embodiment of the present disclosure;

FIG. 8 shows a schematic cross-sectional view of the portion of the solar cell of FIG. 7 along line A--A of FIG. 7;

FIG. 9 show a schematic plan view of a portion of a solar cell according to another embodiment of the present disclosure;

FIG. 10 shows a schematic cross-sectional view of the portion of the solar cell of FIG. 9 along line A--A of FIG. 9;

FIG. 11 show a schematic plan view of a portion of a solar cell according to another embodiment of the present disclosure;

FIG. 12 show a schematic plan view of a portion of a solar cell according to another embodiment of the present disclosure;

FIG. 13 shows a schematic cross-sectional view of the portion of the solar cell of FIG. 12 along line A--A of FIG. 12;

FIG. 14 show a schematic plan view of a portion of a solar cell according to another embodiment of the present disclosure;

FIG. 15 shows a schematic cross-sectional view of the portion of the solar cell of FIG. 14 along line A--A of FIG. 14;

FIG. 16 shows a graph of cumulative RS power loss along a conductive finger of uniform composition and geometry from a midpoint of the conductive finger to a busbar; and

FIG. 17 shows a graph of open-circuit voltage (Voc) for solar cell regions with different percentages of metal/silicon interface areas.

### DETAILED DESCRIPTION

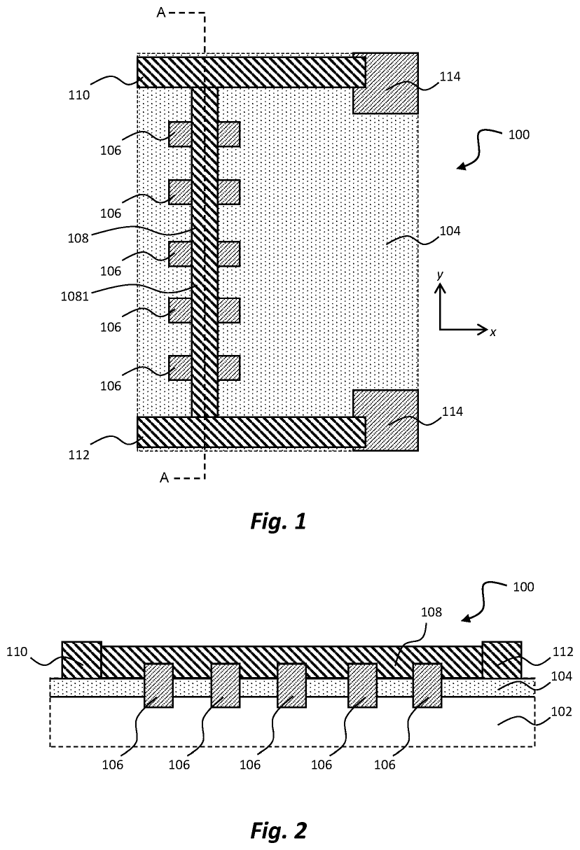

FIG. 1 illustrates a plan view of a portion of a solar cell 100 according to an embodiment of the present disclosure, and FIG. 2 is a cross-sectional view of the portion of the solar cell 100 taken along line A--A of FIG. 1.

The solar cell 100 includes a body of semiconductor material 102 having a dielectric layer 104 over a light-receiving surface of the semiconductor material 102, the dielectric layer 104 providing a light receiving, front surface of the solar cell 100. A plurality of printed fire-through contacts 106 are provided that are exposed at the dielectric layer 104, each contact 106 extending longitudinally in a first dimension x. A conductive finger 108 extends longitudinally in a second dimension y substantially perpendicular to the first dimension x and electrically connects the plurality of contacts 106 to first and second busbars 110, 112 at opposite ends of the conductive finger 108. In this embodiment, the first and/or second busbar 110, 112 is connected to at least one interconnection point (tab) 114. Although not shown in the Figures for the present embodiment, or indeed other embodiments discussed below, the solar cells according to embodiments disclosed herein may include one or more additional conductive fingers. One or more, or all, of the additional conductive fingers may be configured in a substantially identical manner to the conductive fingers that are depicted in the Figures. Further, the number of contacts depicted in the Figures for the present embodiment and any other embodiment is not limiting. The number of contacts used may depend on a number of factors such as the length of the overlying portion(s) of the conductive fingers, the materials selected, desired conductivity values, or otherwise.

The conductive finger 108 has a first portion 1081 that overlays and electrically connects to the plurality of contacts 106. In this embodiment, the first portion 1081 is essentially the entire conductive finger 108, there being no second portion as per some other embodiments. Each of the contacts 106 extends beyond the first portion 1081 of the conductive finger 108 at opposite sides of the first portion 1081 of the conductive finger 108 in the first dimension x, although in alternative embodiments one or more of the contacts may extend beyond the first portion of the conductive finger at one side of the first portion only.

As can be seen in FIG. 2, each of the plurality of contacts 106 passes substantially through the dielectric layer 104 to contact and electrically connect to the semiconductor material 102. However, in alternative embodiments, one or more further, conductive, layers may be provided between semiconductor material 102 and the dielectric layer 104, such as a polysilicon layer or other passivated contact layer, and the plurality of contacts 106 may contact such further layer(s) to achieve electrical connection with the semiconductor material 102.

To fabricate the solar cell 100, the dielectric layer 104 is deposited (e.g., printed/screen printed) on a surface of the semiconductor material 102, along with a fire-through paste to define the plurality of contacts 106, the paste being fired to cause the contacts 106 to pass substantially through the dielectric layer 104. The first portion 1081 of the conductive finger 108 is formed by depositing (e.g. printing/screen printing) a non-fire-through paste over the contacts 106 so that it does not pass substantially through the dielectric layer (and therefore does not make direct contact with the semiconductor material 102 or any conductive layer that may be provided between semiconductor material 102 and the dielectric layer 104). Further heating or annealing steps may be utilised to harden the resulting metallization structure. A heating or annealing step may also be utilised after printing the contacts 106 and interconnection points 114 before printing the conductive finger 106 and the busbars 110, 112.

The plurality of contacts 106 are configured, essentially, as a series of perpendicular ‘dashes’, the series extending in the longitudinal direction y of the conductive finger 108, with each dash extending perpendicularly to the longitudinal direction y of the conductive finger 108. The spacing between the plurality of contacts may be substantially uniform or non-uniform, but is substantially uniform in this embodiment.

The plurality of contacts 106 provide for electrical connection between the conductive finger 108 and the silicon material 102, while reducing a metal/silicon interface area (e.g. as compared to direct interfacing between the conductive finger 108 and the silicon material without the plurality of contacts 106), where the reduction in the metal/silicon interface area may be from e.g. an area of 3% to an area of approximately 2.5% or less, 2% or less, or 1.5% or less, for example. This reduction may greatly reduce a total saturation current density (Jo) of the metal/silicon interface region and therefore increase open-circuit voltage (Voc) of the solar cell. Moreover, by providing contacts 106 that extend beyond the first portion of the conductive finger 108 at one or opposite sides of the conductive finger 108, the metallization arrangement may be particularly suited for a printing processes, such as a screen-printing process, and its associated printing widths and alignment tolerances and capabilities, therefore maintaining high solar cell manufacturing yields.

The use of contacts 106 that extend beyond the first portion 1081 of the conductive finger 108 on a light receiving surface of the solar cell is surprising as it increases shading (as compared to direct interfacing between the conductive finger 108 and the silicon material 102 without the plurality of contacts 106) and therefore reduces the short circuit density (Jsc) of the solar cell. This is particularly the case for the front and main light-receiving surface of a solar cell. However, it has been realised by the present inventors that the reduction in Jsc is offset by the increase in Voc. For example, a Voc increase of 6 mV will be sufficient to increase solar cell efficiency by 0.2% absolute, offsetting shading losses, and providing an additional benefit of lower currents and therefore slight reductions in resistive losses. With the move in the solar cell industry to higher efficiency devices, the reduction in Jo can potentially lead to even larger Voc gains, therefore increasing the potential benefits of the technology, whereby the Voc gain can increase the potential efficiency by 0.35% absolute. Furthermore, with improvements in the alignment capabilities for screen-printing, the shading losses may be reduced by making the degree by which the contacts 106 extend beyond the conductive finger shorter, while still gaining the benefits of the increased VOC. In addition, when this structure is used on a rear light-receiving surface of the solar cell, due to the reduced light intensity, the possible losses due to shading are reduced, while still gaining the benefits of improved VOC.

In some embodiments, each contact 106 may extend beyond the first portion 1081 of the conductive finger 108 by at least 5 micrometres, at least 10 micrometres, at least 15 micrometres, at least 20 micrometres, or at least 25 micrometres, at one or both sides of the first portion 1081 of the conductive finger in the first dimension, for example. Each contact 106 may have a length extending in the first dimension x of between about 30 and 500 micrometres, 30 and 400 micrometres, 30 and 300 micrometres, or 30 and 200 micrometres, for example. The first portion 1081 of the conductive finger 108 may have a width extending in the first dimension x of between about 10 and 100 micrometres, 20 and 80 micrometres, 20 and 60 micrometres, or 30 and 50 micrometres, for example. The first portion 1081 of the conductive finger 108 may have a width extending in the first dimension that is less than about 90%, 80%, 70%, 60%, or 50%, of the length of each contact 106 in the first dimension, for example. A spacing between adjacent contacts 106 of the plurality of contacts along the length of the finger 108 may be between about 60 and 500 micrometres, 100 and 400 micrometres, or 200 and 400 micrometres, for example. A thickness (height) of each contact may be less than 20 micrometres, less than 10 micrometres, between 5 and 10 micrometres, or less than 5 micrometres, for example

The contacts 106 and interconnection points 114 in this embodiment are formed of fired-through (FT) silver and the first portion 1081 of the conductive finger 108, along with busbars 110 and 112, is formed of non-fired through (NFT) aluminium or copper or silver/aluminium alloy or tin or tin/silver alloy, for example. As shown in FIGS. 1 and 2, such a metallization structure is applied to, for example, the front surface of PERC (n-type contact) solar cell.

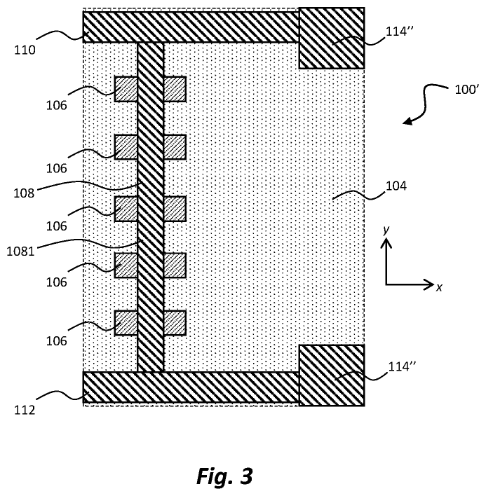

In an alternative embodiment, as shown in FIG. 3, a solar cell 100′ is provided that is the same as the solar cell 100 of FIGS. 1 and 2 except that the interconnection points 114′ are formed in substantially the same manner as the first portion 1081 of the conductive finger and the first and second busbars 110, 112 (e.g. by virtue of being of the same metallic material and/or also being formed non-fired through (NFT) the dielectric layer 104). The arrangement shown in FIG. 3 may be particularly suited for forming via a two-step printing process, in which the metal of the contacts 106 is deposited in a first print step and the metal of the first portion 1081 of the conductive finger 108, the first and second busbars 110, 112 and the interconnection points 114′, is deposited in a second print step, e.g., before or after the first print step.

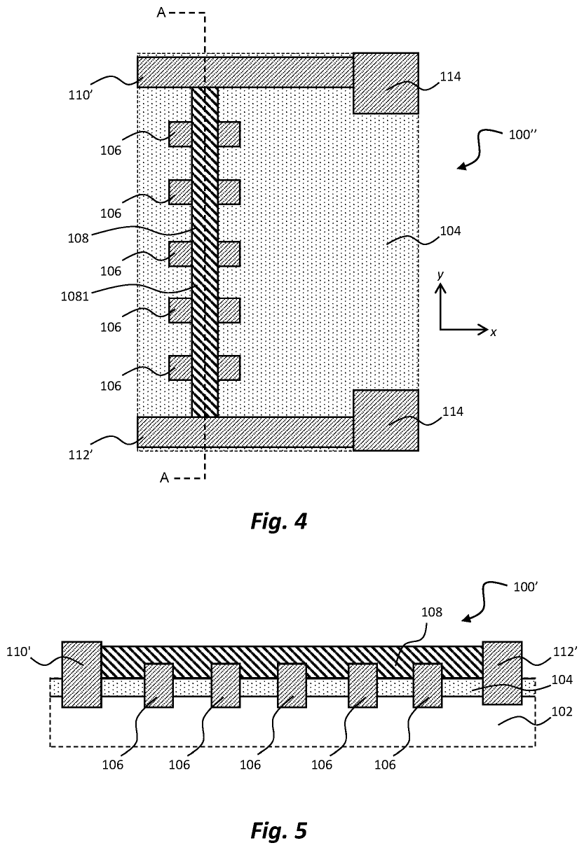

In an alternative embodiment, as shown in FIGS. 4 and 5, a solar cell 100″ is provided that is the same as the solar cell 100 of FIGS. 1 and 2 except for the configuration of the first and second busbars 110′, 112′, which first and second busbars 110′, 112′ are formed in substantially the same manner as the contacts 106. In particular, like the contacts 106, the first and second busbars 110′, 112′ are formed of fired-through (FT) silver, although with a higher metal lay down than the contacts 106 and with opposite ends of the conductive finger 108 contacting sides of the first and second busbars 110′, 112′. In alternative embodiments the first and second busbars 110′, 112′ may have the same metal lay down as the contacts 106 and/or opposite end regions of the conductive finger 108 may extend on top of the first and second busbars 110′, 112′.

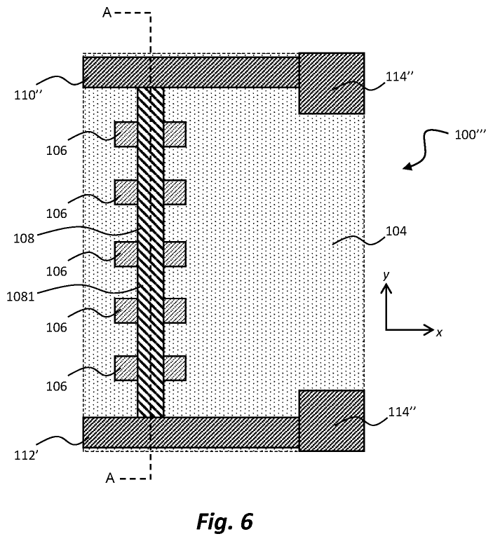

In another alternative embodiment, as shown in FIG. 6, a solar cell 100′″ is provided that is the same as the solar cell 100 of FIGS. 1 and 2 except for the configuration of the first and second busbars 110″, 112″ and interconnection points 114″, which first and second busbars 110′, 112′ and interconnection points 114″ are formed in a different manner to the contacts 106 and the first portion 1081 of the conductive finger 108 (e.g. by virtue of the metal selected and/or the choice of being fired (FT) or non-fired through (NFT) the dielectric layer 104).

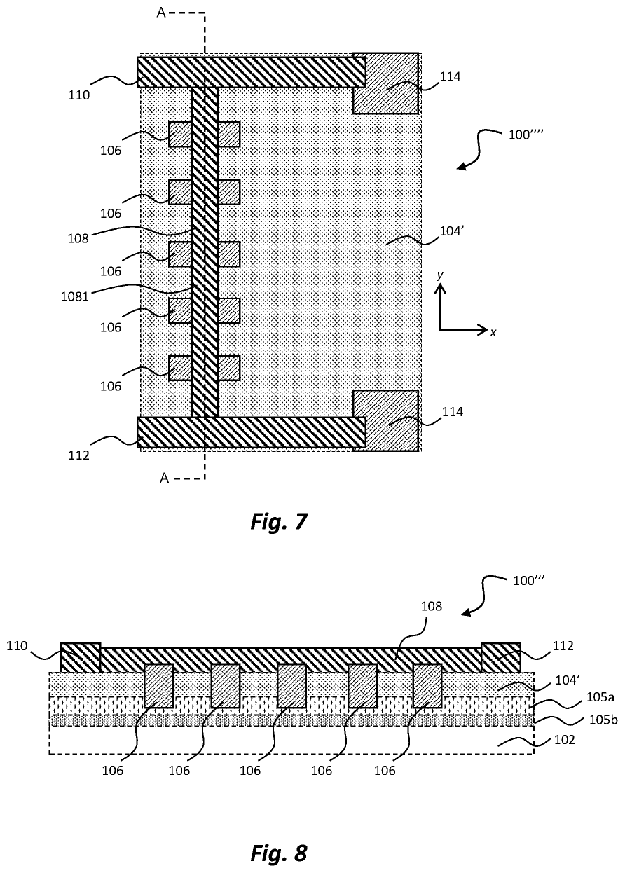

In yet another alternative embodiment, as shown in FIGS. 7 and 8, a solar cell 100″″ is provided that has a similar metallisation structure to the solar cell 100 of FIGS. 1 and 2 except that it is applied to the rear, light receiving surface for the n-type contact of a TOPCon solar cell, and therefore a solar cell with a different layer construction. The solar cell 100″″ includes a dielectric layer 104′, and in particular an antireflection coating/capping layer 104′, e.g. of SiNx, through which fired through (FT) contacts 106 extend. A tunnel oxide layer 105b is located on top of the silicon body 102 and a doped polysilicon layer 105a (conductive passivation layer) is located on top of the tunnel oxide layer 105b such that the tunnel oxide layer 105b and the polysilicon layer 105a are positioned between the silicon body 102 and the dielectric layer 104′. The contacts 106 are in direct contact with the polysilicon layer 105a.

In general, the plurality of contacts, the first portion of the conductive finger, the second portion of the conductive finger (when present as discussed below), the first and second busbars, and the interconnection points (when present) may each be formed of a selection of different metallic materials, whether a pure form of metal or a combination (e.g. alloy) of metals, and the selection of metallic materials may be made in order to reduce silver consumption, reduce a number of printing or metal deposition steps and/or otherwise. Some or all of these advantages regarding selection and printing/deposition of materials may be achieved according to the present disclosure even if different shapes and configurations of the plurality of contacts are used beyond those illustrated and described above, including contacts that have longitudinal dimensions that are parallel with, or angled obliquely relative to, the longitudinal dimension of the conductive finger, and which may or may not extend beyond the first portion of the conductive finger at one or both sides of the conductive finger in the first dimension.

As a set of non-limiting examples, metallisation schemes/structures that may be applied to different types of solar cells having a metallization structure that is the same or similar to that of FIGS. 1 and 2, or FIG. 3, or FIGS. 4 and 5, or FIG. 6, or FIGS. 7 and 8, and which may achieve one or more of the described advantages or otherwise, are set forth in Tables 1 and 2 below. Table 1 presents a metallization scheme that may be carried out with only two printing steps, and Table 2 presents a metallization scheme that may be carried out with only three printing steps. In Table 1, although the busbars are shown having metallization corresponding to the interconnection points (tabs), the metallization of the busbars may correspond alternatively to either the contacts or the first portion. Further, in Table 2, in addition to the materials identified for the interconnection points (tabs), other options include use of solderable pastes such as solderable copper-based pastes, or electrically conductive adhesives, and whether or not three or more printing steps are taken. Where a metallization scheme is carried out using only two printing steps, it will be recognised that only two different types of metallic materials with their associated deposition approach (e.g. FT/NFT) may be selected within each table row to form all of the different features (i.e. contacts/first finger portion/busbars/interconnection points) and, where a metallization scheme is carried out using only three printing steps, it will be recognised that only three different types of metallic materials and their associated deposition approach may be selected to form the different features.

TABLE 1
Two-print step with uniform conductive finger

| | Contacts | First portion | | |
|---|---|---|---|---|
| | (dashes) | of conductive | Interconnection | |
| Solar cell type | (FT) | finger (NFT) | points (tab) | Busbars |
| PERC n-type | Ag | Al or Cu | Ag (FT) | Ag (FT) |
| contact | | | | |
| PERC n-type | Ag | Ag/Al | Ag (FT) or Ag/Al (NFT) | Ag (FT) or Ag/Al (NFT) |
| contact | | | | |
| PERC n-type | Ag | Tin, Tin/silver, | Ag (FT) or Tin (NFT), | Ag (FT) or Tin (NFT), |
| contact | | or Ag coated copper | Tin/silver (NFT), or | Tin/silver (NFT), or |
| | | | Ag coated copper (NFT) | Ag coated copper (NFT) |
| PERC n- | Ag | Reduced silver | Ag (FT) or reduced silver | Ag (FT) or reduced silver |
| type contact | | or silver-free | (NFT) or silver-free (NFT) | (NFT) or silver-free (NFT) |
| PERC p- | Al | Ag/Al | Ag/Al (NFT) | Ag/Al (NFT) |
| type-contact | | | | |
| TOPCon n- | Ag | Al or Cu | Ag (FT) | Ag (FT) |
| type contact | | | | |
| TOPCon n- | Ag | Ag/Al | Ag (FT) or Ag/Al (NFT) | Ag (FT) or Ag/Al (NFT) |
| type contact | | | | |
| TOPCon n- | Ag | Tin, Tin/silver, | Ag (FT) or Tin (NFT), | Ag (FT) or Tin (NFT), |
| type contact | | Ag coated copper | Tin/silver (NFT), or | Tin/silver (NFT), or |
| | | | Ag coated copper (NFT) | Ag coated copper (NFT) |
| TOPCon n- | Ag | Reduced silver | Ag (FT) or reduced silver | Ag (FT) or reduced silver |
| type contact | | or silver-free | (NFT) or silver-free (NFT) | (NFT) or silver-free (NFT) |
| TOPCon p- | Ag/Al | Al or Cu | Ag/Al (FT) | Ag/Al (FT) |
| type contact | | | | |
| TOPCon p- | Ag/Al | Ag/Al | Ag/Al (FT or NFT) | Ag/Al (FT or NFT) |
| type contact | | | | |
| TOPCon p- | Ag/Al | Reduced silver | Ag/Al (FT) or reduced silver | Ag/Al (FT) or reduced silver |
| type contact | | or silver-free | (NFT) or silver-free (NFT) | (NFT) or silver-free (NFT) |
| TOPCon p- | Al | Ag/Al | Ag/Al (NFT) | Ag/Al (NFT) |
| type contact | | | | |

TABLE 2
Three-print step with uniform conductive finger

| | | First portion | | |
|---|---|---|---|---|
| | Contacts | of conductive | Interconnection | |
| Solar cell type | (dashes) (FT) | finger (NFT) | points (tab) | Busbars |
| PERC n- | Ag | Al, Cu, Ag coated | Ag/Al (NFT) | Ag/Al (NFT) |
| type contact | | Cu, tin, tin/silver | | |
| PERC n- | Ag | Al, Cu, Ag coated Cu | Tin (NFT) or tin/ | Tin (NFT) or |
| type contact | | | silver (NFT) | tin/silver (NFT) |
| PERC n- | Ag | Reduced silver or | Tin (NFT) or tin/ | Tin (NFT) or |
| type contact | | | silver (NFT) | tin/silver (NFT) |
| PERC p- | Al | Al or Cu | Ag/Al (FT or NFT) or | Ag/Al (FT or NFT) or |
| type-contact | | | tin (NFT), or | tin (NFT), or |
| | | | tin/silver (NFT) | tin/silver (NFT) |
| TOPCon n- | Ag | Al, Cu or Ag coated | Ag/Al (NFT) | Ag/Al (NFT) |
| type contact | | Cu, tin, tin/silver | | |
| TOPCon n- | Ag | Reduced silver or | Tin (NFT) or | Tin (NFT) or |
| type contact | | silver-free | tin/silver (NFT) | tin/silver (NFT) |
| TOPCon p- | Ag/Al | Al or Cu | Ag/Al (NFT) | Ag/Al (NFT) |
| type contact | | | | |
| TOPCon p- | Al | Al or Cu | Ag/Al (FT or NFT) | Ag/Al (FT or NFT) |
| type contact | | | | |

When the contacts 106 are formed using fire-through Al-based pastes, this creates the opportunity for small-area local p+ doped regions, such as the rear contact of PERC (p-type contact), or a selective emitter for the front surface of TOPCon (p-type contact). For PERC, a non-fire-through Al-paste can then be used for fingers and busbars, followed by the conventional Ag/Al tabbing region, for example. This can be achieved in a 3-step printing process. For TOPCon (p-type contact) on the front light receiving surface, when using pure Al fire-through paste to form contacts 106, a non-fire-through Ag/Al paste can be used for metal fingers and busbars and tabbing points, again with no extra Ag consumption compared to the current state of the art. This can be achieved in a 2-print process. Hence, in these instances, the technology allows for reduced metal/silicon interface area to increase solar cell performance without increasing Ag consumption or impacting on interconnection.

As indicated, the approach described in the present disclosure has the significant potential to reduce silver consumption, without impacting on the ability to use aspects of current technology to form metal/silicon interface regions or interconnection. For example, known fire-through pastes can be used to form the metal/silicon interface region and for tabbing regions with standard interconnection processes. Separate non-fire-through pastes can then be used in the finger and busbar regions. This allows a 2-print process to be used, for example.

Current industrial solar cells are using an increasing number of busbars (BB), such as solar cells using the multibusbar technology (e.g. 9, 12 or 13 BB), reducing resistance impacts in the conductive fingers and busbars regions, thereby relaxing the need for the use of silver pastes for high conductivity. For example, with reference to Table 3 below, in shifting from a 5BB to 13BB design, finger conductivity can be reduced by a factor of 6, while still only resulting in −0.5% relative series resistance (RS-related power loss, corresponding to only 0.1% absolute efficiency). In addition, bulk conductivity in the busbars can be significantly reduced without impacting solar cell performance (>10x). Currently, there are copper (Cu) pastes with a reported resistivity of 17 Racm, roughly 3.5 times that of silver (5 Racm), and aluminium pastes with 35-40 Racm, well within resistivity requirements, and which are already used on the rear surface of bifacial PERC cells. On the other hand, pure tin and solders can have resistivities in the vicinity of 10 μΩcm. It is also noted that a 1% relative power loss from RS is equivalent to a 0.2% absolute loss in efficiency.

TABLE 3
Series resistance (RS) power loss (Ploss) in fingers and busbars assuming
40 μm finger width, 16 μm finger height, 1.3 mm finger spacing. 500
μm width for the 5BB design and 100 μm width for the 9BB and 13BB design.
VMP = 600 mV, JMP = 35 mA/cm², and bulk resistivity of 5 μΩ · cm (silver).

| | | | | RS Busbar Pₗₒₛₛ |
|---|---|---|---|---|
| | Finger RS Pₗₒₛₛ | Finger RS Pₗₒₛₛ | RS busbar Pₗₒₛₛ | (normalised |
| Design | (% rel) | (% rel) | (% rel) | to 5BB) |
| 5BB | 0.50 | 100% | 0.675 | 100% |
| (6 tabs/busbar) | | | | |
| 9BB | 0.154 | 30% | 0.094 | 14% |
| (12 tabs/busbar) | | | | |
| 13BB | 0.074 | 15% | 0.019 | 3% |
| (22 tabs/busbar) | | | | |

Conductive fingers and busbars can be formed using metal pastes with reduced level of silver content (e.g. Al/Ag pastes, Ag coated copper pastes, tin-silver), or be silver free, such as aluminium-, copper- or tin-based pastes. This provides significant potential for manufacturing cost reductions and silver reduction, while an increase in series resistance can be minimised. In general metallic materials in the present disclosure with a reduced level of silver content (e.g. “reduced silver pastes”, for example) may have a silver content of less than 70%, less than 50% or less than 30% wt % of silver, for example Material with a reduced level of silver may comprise a combination of silver and any one or more of aluminium, copper and tin, for example, or otherwise.

For a PERC or TOPCon cell, whereby silver may be used only for, e.g., the contacts (1% metal/silicon interface area) and interconnection points (for example, 9× busbars 100 micron wide with 12 tabs per busbar 600 micron×1 mm and a 16 micrometers printing height), silver usage may be reduced to about 20 mg by replacing a conventional Ag finger with Al or copper, for example. Further reductions can be made by also replacing the busbar (down to e.g., 14 mg), or by reducing the print height for the dash contacts/interconnection points down to e.g., 5-10 micron, giving around 5-10 mg of silver while still maintaining silver interconnection points, for example. This is compared to an estimated 45 mg of silver required for a standard metallization approach on the front surface of a PERC solar cell (156×156 mm cell).

For a TOPCon solar cell, whereby aluminium may be used for the fire-through contacts, and non-fire-through aluminium or copper for the conductive fingers, approximately 10 mg of silver may be required for the front surface busbar and the interconnection points, assuming 16 micron height, for example. This could be reduced to approximately 3-5 mg by only using silver for the interconnection points, for example. Importantly, the interconnection points (tabbing regions), if fire-through, may only add 0.5-1% metal/silicon interface (total of 1.5-2%), which is still less than for a standard metallization approach, while still greatly reducing silver consumption.

Further developments in interconnection technology may also avoid the need for silver-based tabbing regions.

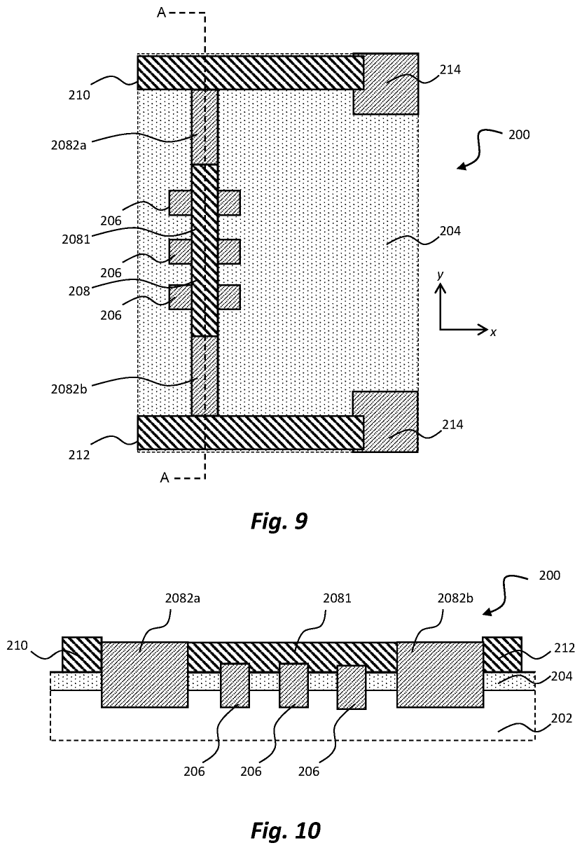

With reference to FIGS. 9 and 10, in an alternative embodiment of the present disclosure, a solar cell 200 is provided that includes a body of semiconductor material 202, a dielectric layer 204, a plurality of contacts 206, a conductive finger 208 having a first portion 2081, first and second busbars 210, 212, and one or more interconnection points 214, similar to the preceding embodiment. However, in this embodiment, the conductive finger 208 has a ‘hybrid’ design, by comprising at least one second portion 2082, and more particularly two second portions 2082a, 2082b in this embodiment, in addition to the first portion 2081. The two second portions 2082a, 2082b are located at opposite ends of the first portion 2081 of the conductive finger 208. Each second portion 2082a, 2082b passes substantially through the dielectric layer. Each second portion 2082a, 2082b of the conductive finger 2082 is formed by depositing a fire-through paste, the paste being fired to cause each second portion 2082a, 2082b to pass substantially through the dielectric layer 204.

As can be seen in FIG. 10, each second portion 2082a, 2082b of the conductive finger 208 passes substantially through dielectric layer 204 to contact and electrically connect to the semiconductor material 202. However, in alternative embodiments, one or more further, conductive, layers may be provided between semiconductor material 202 and the dielectric layer 204, such as a polysilicon layer or passivated contact layer, and each second portion 2081a, 2082b of the conductive finger 208 may contact such further layer(s) to achieve electrical connection with the semiconductor material 202.

The embodiment of FIGS. 9 and 10 provides one example of a hybrid finger that may be used according to the present disclosure, e.g., to take into account resistive losses within solar cells. Resistive losses in solar cells occur when electrical current flows through the metal conductive fingers and busbars. These losses reduce the overall efficiency of the solar cell. Typical approaches to reducing the resistive losses are to increase the physical size of conductive fingers and busbars, and/or using metal with higher conductivity.

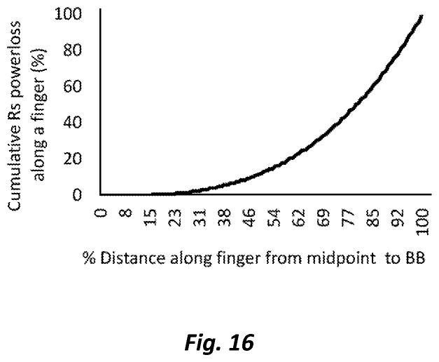

Photocurrent is generated fairly uniformly across a solar cell, collected by the conductive finger whereupon it travels to the busbar. As a result of the uniform current generation, the photocurrent flowing through a given conductive finger increases from the midpoint of the conductive finger in a direction towards a busbar. The increasing current means that the cumulative resistive losses along a conductive finger increase from the midpoint of the conductive finger towards the busbar. Cumulative resistive losses along a conductive finger are shown in FIG. 16, where the right hand side of the horizontal axis is towards the busbar (BB). The cumulative resistive losses and therefore power losses increase quadratically with distance along the conductive finger from the midpoint towards the busbar (BB). Therefore, the majority of the resistive losses and power losses in the conductive finger occur in the vicinity of the busbars rather than in the vicinity of the midpoint between the busbars.

In fact, from FIG. 16, which assumes a finger of uniform composition and dimensions, it is apparent that approximately 50% of the power loss occurs in the last 20% of the conductive finger closest to each busbar, from the midpoint of the conductive finger, with the power loss increasing quadratically along the length of the conductive finger. In addition, the first 50% of the conductive finger from the midpoint to the busbar only contributes about 13% of the power loss in the finger. Therefore, significant conductivity is mostly required in the conductive finger near the busbars, rather than near the midpoint.

The solar cell 200 of FIGS. 9 and 10, which includes a conductive finger 208 with a ‘hybrid’ design, takes advantage of the above observations of FIG. 16. The configuration of the first and second portions 2081, 2082a, 2082b of the conductive finger 208 are such that each second portion 2082a, 2082b has a higher conductivity than the first portion 2081. The arrangement recognises that the first portion 2081, which is in the vicinity of the midpoint of the conductive finger 208 where resistive losses are lower or negligible, can tolerate a lower conductivity (higher resistance), but each second portion 2082a, 2082b, which are in the vicinity of the first and second busbars 210, 212, respectively, where resistive losses are more significant, should have a higher conductivity (lower resistance) to ensure suitable solar cell performance.

The arrangement of the conductive finger 208 may provide for better use of materials and can save costs. For example, in some embodiments, the second portions 2082a, 2082b of the conductive finger 208 comprise silver, which has a relatively high conductivity relative to other metals. The first portion 2081 of the conductive finger 208 is then made from a lower conductivity metal such as copper, Ag coated copper, tin, tin alloy, tin-silver, aluminium or an aluminium/silver alloy, and relies on electrical connection to the semiconductor material 202 through the plurality of contacts 206 which may be formed of silver, but may use significantly less silver than would otherwise be required. It will be appreciated that lower conductivity metals such as copper and aluminium are less costly than silver, thereby reducing the overall cost of the conductive finger 208 relative to a conductive finger made entirely of silver. The arrangement of metallization in the solar cell of FIGS. 9 and 10 may be applied, as an example, to n-type contact of a PERC solar cell.

Replacing silver with, for example, copper or another metal in 50% of the finger 402 (assuming the Cu finger has roughly 3.5x the bulk resistance as for a silver finger) would save ˜17 mg of silver from the finger, reducing the overall silver consumption on the front surface of a PERC solar cell by −30%, for example. The relative series resistance related power loss in the finger may increase by 26%, for example. For a 5 BB solar cell this would increase series resistance power loss from 0.49% to 0.62%, translating to a reduced efficiency of only 0.03% absolute, and still resulting in a reduced manufacturing cost.

For a 9 BB or 13 BB solar cell, this extra power loss would be reduced further to <0.01% absolute. As such for solar cells with a higher number of busbars, a larger fraction of the conductive finger can be replaced with a reduced conductivity metal without severely impacting performance, therefore providing increased opportunity to reduce costs related to silver consumption.

Were the contacts 206 not employed, with the conductive finger 208 directly interfacing with the silicon 202, use of two separate metals and printing techniques along the conductive finger 208 would likely not be suitable for forming the metal/silicon interface region. For example, if a portion of the conductive finger was copper, undesirable copper diffusion into the silicon could cause light-induced degradation, therefore reducing efficiency. If a portion of the conductive finger was aluminium, it might cause shunting for an n-type contact due to the formation of an Al—Si alloyed p+ region for temperatures over 577° C. On the other hand, the proposed technology can be used to allow two separate metallic materials to be used in the conductive finger 208, while only using a single metal for metal/silicon interface formation. In particular, in the second portions 2082a, 2082b of the conductive finger 208, the fire-through paste is used to form what might be considered more conventional finger regions, while in the first portion 2081, a non-fire-through printing process is used to connect to the contacts 206. Overall, silver usage may therefore be reduced, while minimising the requirement for a third printing process, balancing resistive losses, reducing shading losses and/or reducing metal/Si interface compared to a conventional design.

In this and other embodiments where the conductive finger 208 comprises the different first and second portions, the contacts 206 may be configured as illustrated and in accordance with previous embodiments such as to extend longitudinally in a direction that is substantially perpendicular to the longitudinal dimension of the conductive finger 208. However, alternatively, different configurations of contacts may be used, including contacts that have longitudinal dimensions that are parallel with, or angled obliquely relative to, the longitudinal dimension of the conductive finger, and which may or may not extend beyond the first portion of the conductive finger at one or both sides of the conductive finger in the first dimension.

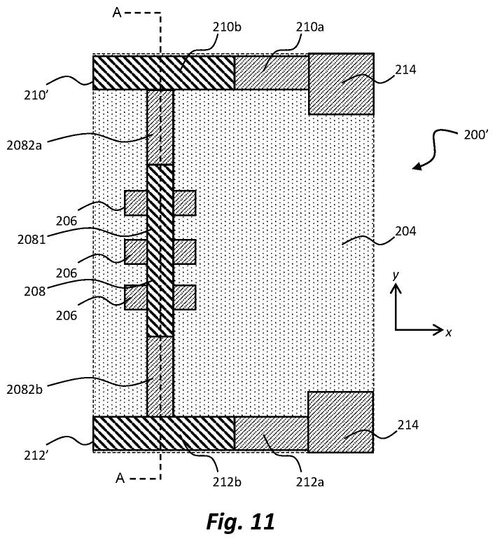

With reference to FIG. 11, in an alternative embodiment of the present disclosure there is provided a solar cell 200′ that is the same as the solar cell 200 of FIGS. 9 and 10 except for the configuration of the first and second busbars 210′, 212′, which first and second busbars 210′, 212′ have two different portions 210a, 210b, 212a, 212b formed of different metals. In particular, a portion 210a, 212a of each busbar 210′, 212′ that is closest to the interconnection point 214 is formed of a metal that provides lower resistive losses (has higher conductivity) than a portion 210b, 212b of each busbar 210′, 212′ that is closer to the conductive finger 208 and/or a midpoint of the busbar 210, 212′ between interconnection points. In general, the busbars 210b, 212b in this and any other embodiments can take on a similar ‘hybrid’ design as for the conductive fingers 208, e.g. to provide for better use of materials and save costs.

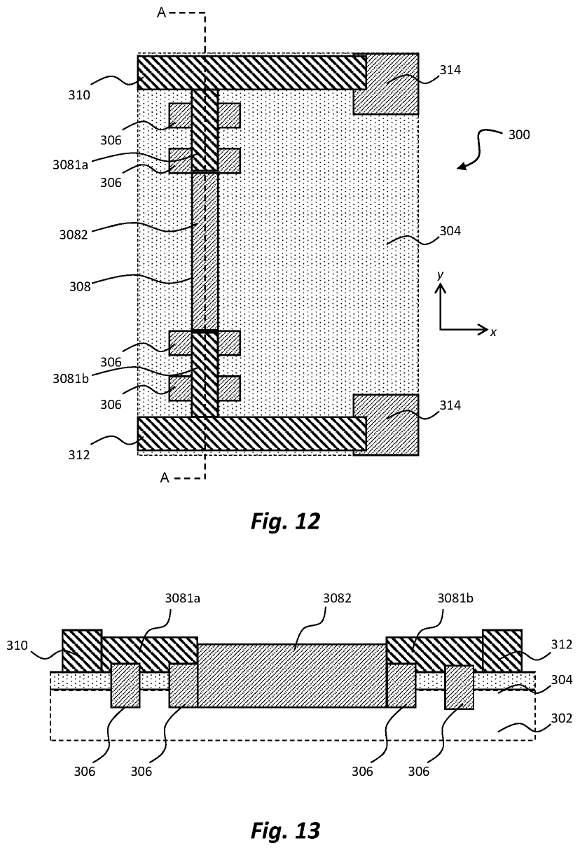

With reference to FIGS. 12 and 13, in an alternative embodiment of the present disclosure, a solar cell 300 is provided that includes a body of semiconductor material 302, a dielectric layer 304, a plurality of contacts 306, a conductive finger 308 having a first portion 3081 and a second portion 3082, first and second busbars 310, 312, and one or more interconnection points 314, similar to the preceding embodiment. However, in this embodiment, the ‘hybrid’ design of the conductive finger 308 is different, having two first portions 3081a, 3081b, in addition to the second portion 3082. The two first portions 3081a, 3081b are located at opposite ends of the second portion 3082 of the conductive finger 308 and each overlay and electrically connect to a respective set of the plurality of contacts 306. The second portion 3082 passes substantially through the dielectric layer 304. The second portion 3082 is formed by depositing a fire-through paste, the paste being fired to cause the second portion 3082 to pass substantially through the dielectric layer 304.

In this embodiment, the metallization structure may again take advantage of the above observations of FIG. 16. The configuration of the first and second portions 3081a, 3081b, 3082 are such that each first portion 3081a, 3081b has a higher conductivity than the second portion 3082. The arrangement recognises that the second portion 3082, which is in the vicinity of the midpoint of the conductive finger 308 where resistive losses are lower or negligible, can tolerate a lower conductivity (higher resistance) resistance, but each first portion 3081a, 3081b, which are in the vicinity of the first and second busbars 310, 312, respectively, where resistive losses are more significant, should have a higher conductivity (lower resistance) to ensure suitable solar cell performance.

The arrangement of the finger 308 again may provide for better use of materials and can save costs. For example, in some embodiments, the first portions 3081a, 3081b comprise silver, which has a relatively high conductivity relative to other metals. The second portion 3082 is then made from a lower conductivity metal such as copper, tin, tin alloy, aluminium or an aluminium/silver alloy. The arrangement of metallization in the solar cell of FIGS. 12 and 13 may be applied, as an example, to a PERC or TOPCon solar cell.

In alternative embodiments, whether for PERC or TOPCon, the use of an all-silver printed metallization arrangement is not precluded. For example, even through use of all-silver, costs may be saved through use of reduced metal laydown (reduced metal thickness/height) at lower conductivity regions. In general, therefore, hybrid conductive finger arrangements according to the present disclosure may include first and second portions that have different thicknesses/heights, in addition to, or as an alternative to, the first and second portions being formed of different metallic materials.

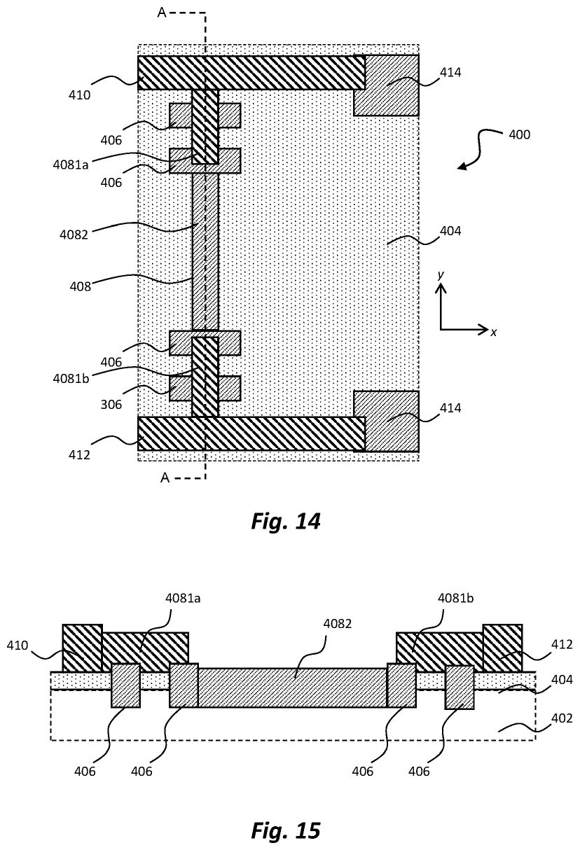

An example of an all-silver printed metallization arrangement is shown in FIGS. 14 and 15, where a solar cell 400 is provided that includes a body of semiconductor material 402, a dielectric layer 404, a plurality of contacts 406, a conductive finger 408 having first portions 4081a, 4081b and a second portion 4082, first and second busbars 410, 412, and an interconnection point 414, similar to the preceding embodiment. However, in this embodiment, the fire-through second portion 4082, which is in the vicinity of the midpoint of the conductive finger 408 where resistive losses are lower or negligible, has a reduced metal laydown (e.g. 5-10 micrometres), the second portion 4082 therefore having a lower height than the first portions 4081a, 4081b (note the thicknesses of the layers in FIG. 15 and other Figures are not necessarily drawn to scale). In the conductive finger 408, the silver laydown in the high-resistance end regions (first portions 4081a, 4081b) may be a standard laydown (e.g. 16 micrometres).

It will be appreciated by a skilled person in the art that such different geometries of the first and second portions of the conductive fingers may be applied to other embodiments, and not necessarily embodiments that have a single material across the conductive finger.

As a set of non-limiting examples, metallization schemes/structures that may be applied to different types of solar cells having metallization structures including hybrid conductive fingers as described above, and which may achieve one or more of the described advantages, are set forth in Tables 4 and 5 below. Table 4 presents a metallization scheme that may be carried out with only two printing steps, and Table 5 presents a metallization scheme that may be carried out with only three printing steps. In these tables, although the busbars are shown having metallization corresponding to the interconnection points (tabs), the metallization of the busbars may correspond alternatively to any one of the contacts, or first portion or second portion of the conductive finger, and ‘hybrid’ designs of the busbars may also be employed, e.g. in line with discussions above with respect to FIG. 11. Further, in Table 5, in addition to the materials identified for the interconnection points (tabs), other options include use of solderable pastes such as copper-based pastes, or electrically conductive adhesives, and whether or not three or more printing steps are taken. Where a metallization scheme is carried out using only two printing steps, it will be recognised that only two different types of metallic materials with their associated deposition approach (e.g. FT/NFT) may be selected within each table row to form all of the different features (i.e. contacts/first finger portion/second finger portion/busbars/interconnection points) and, where a metallization scheme is carried out using only three printing steps, it will be recognised that only three different types of metallic materials and their associated deposition approach may be selected to form the different features.

TABLE 4
Two-print steps with hybrid conductive finger. The first or second
portion with the highest conductivity is closest to the busbar.

| | | First portion | | | |
|---|---|---|---|---|---|
| | Contacts | of conductive | Interconnection | | Solar cell |
| Solar cell type | (dashes) (FT) | finger (NFT) | points (tab) | Busbars | type |
| PERC n- | Ag | Al, Cu, Ag-coated | Ag | Ag (FT) | Ag (FT) |
| type contact | | copper, tin | | | |
| | | or tin-silver | | | |
| PERC n- | Ag | Ag/Al | Ag | Ag (FT) or | Ag (FT) or |
| type contact | | | | Ag/Al (NFT) | Ag/Al (NFT) |
| PERC n- | Ag | Tin | Ag | Ag (FT) or tin | Ag (FT) or tin |
| type contact | | | | (NFT) | (NFT) |
| PERC n- | Ag | Tin-silver | Ag | Ag (FT) or tin- | Ag (FT) or tin |
| type contact | | | | silver (NFT) | (NFT) |
| PERC n- | Ag | Reduced | Ag | Ag (FT) or | Ag (FT) or |
| type contact | | silver or | | reduced silver | reduced silver |
| | | silver-free | | (NFT) or silver- | (NFT) or silver- |
| | | | | free (NFT) | free (NFT) |
| PERC p- | Al | Ag/Al | Al | Ag/Al (NFT) | Ag/Al (NFT) |
| type-contact | | | | | |
| TOPCon n- | Ag | Al or Cu | Ag | Ag (FT) | Ag (FT) |
| type contact | | | | | |
| TOPCon n- | Ag | Ag/Al | Ag | Ag (FT) or | Ag (FT) or |
| type contact | | | | Ag/Al (NFT) | Ag/Al (NFT) |
| TOPCon n- | Ag | Reduced | Ag | Ag (FT) or | Ag (FT) or |
| type contact | | silver or | | reduced silver | reduced silver |
| | | silver-free | | (NFT) or silver- | (NFT) or silver- |
| | | | | free (NFT) | free (NFT) |
| TOPCon n- | Ag | Tin | Ag | Ag (FT) or Tin | Ag (FT) or Tin |
| type contact | | | | (NFT) | (NFT) |
| TOPCon p- | Ag/Al | Al or Cu | Ag/Al | Ag/Al (FT) | Ag/Al (FT) |
| type contact | | | | | |
| TOPCon p- | Ag/Al | Ag/Al | Ag/Al | Ag/Al (NFT or FT) | Ag/Al (NFT or FT) |
| type contact | | | | | |
| TOPCon p- | Al | Ag/Al | Al | Ag/Al (NFT) | Ag/Al (NFT) |
| type contact | | | | | |

TABLE 5
Three-printing step with hybrid conductive finger hybrid finger. The
portion with the highest conductivity is closest to the busbar.

| | Contacts | First | Second | | |
|---|---|---|---|---|---|
| Solar cell | (dashes) | portion | portion | Interconnection | |
| type | (FT) | (NFT) | (FT) | point (tab) | Busbars |
| PERC n-type | Ag | Al or Cu | Ag | Ag/Al (NFT) | Ag/Al (NFT) |
| contact | | | | | |
| PERC p- | Al | Al or Cu | Al | Ag/Al (NFT or FT) | Ag/Al (NFT or FT) |
| type-contact | | | | | |
| TOPCon n- | Ag | Al or Cu | Ag | Ag/Al (NFT) | Ag/Al (NFT) |
| type contact | | | | | |
| TOPCon n- | Ag | Ag/Al | Ag | Ag (NFT) | Ag (NFT) |
| type contact | | | | | |
| TOPCon p- | Ag/Al | Al or Cu | Ag/Al | Ag/Al (NFT) | Ag/Al (NFT) |
| type contact | | | | | |
| TOPCon p- | Al | Al | Al | Ag/Al (NFT or FT) | Ag/Al (NFT or FT) |
| type contact | | | | | |

In some embodiments, solar cells may be provided that are configured according to solar cells as discussed above, although not necessarily using a fire-through printing step to form the plurality of contacts or second portion of the conductive finger, for example. It will be recognised that advantages as described above, such as reduced as silver consumption, may be achieved where techniques other than fire-through printing are used.

Experimental Example

PERC solar cells according to the present disclosure were fabricated with metallisation that included, at a light-receiving surface of the solar cell, a plurality of fire-through (FT) contacts (dashes) and a non-fire-through (NFT) ‘H-pattern’ of conductive fingers and busbars, the conductive fingers overlaying and electrically connecting the busbars to the plurality of contacts. The solar cells were fabricated with four different regions, each region having different respective percentages of metal/silicon interface area at the light-receiving surface. The different metal/silicon interface areas were achieved by employing different numbers of, and spacing between, the dashes at each region, as set forth in Table 6.

TABLE 6
Metal/silicon interface areas for different regions of solar cells

| | | |
|---|---|---|
| Region of solar | Spacing between | Metal/silicon |
| cell | contacts (dashes) (FT) | interface area |

| | | | |
|---|---|---|---|
| Region 1 | 1550 | μm | 0.5% |
| Region 2 | 775.4 | μm | 1.0% |
| Region 3 | 517 | μm | 1.5% |
| Region 4 | 387.7 | μm | 2.0% |

A PERC solar cell was also fabricated as a control, the control solar cell having a traditional metallisation scheme with fire-through (FT) conductive fingers and busbars in a corresponding ‘H-pattern’, therefore having a significantly higher metal/silicon interface area (roughly 3% in the finger regions).

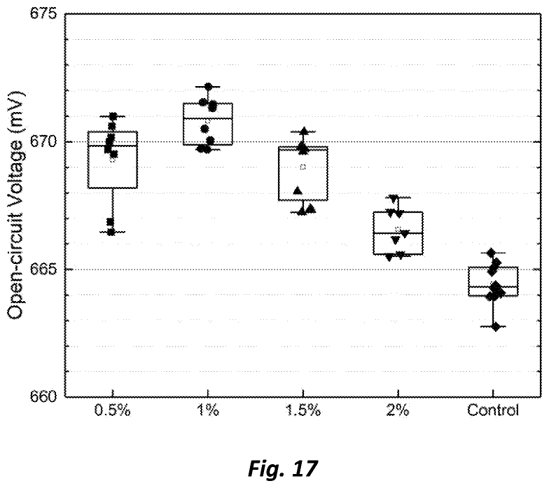

Using photoluminescence (PL) imaging, the open circuit voltage (Voc) at each region was determined and compared to the control, the results being represented in FIG. 17. As can be seen from FIG. 17, the regions of the cell with the metal/silicon interface areas of 0.5%, 1%, 1.5% and 2% saw significant improvements in Voc compared to the control. Gains in Voc of up to 6.3 mV or even higher can be seen. The results confirm that metallisation-to-solar cell contact areas of about 2.5% or 2% or lower may be highly advantageous to increase Voc, with the maximum gain being at about 1% contact area in this example. It is understood, however, that it may be preferable to employ metal/silicon interface areas of at least 0.5%, e.g. 0.5 to 2% or 1 to 2% or 0.5% to 1.5%, due to increases in contact resistance, lower fill factors and/or lower short-circuit current density (Jsc), when metallisation-to-solar cell contact areas are extremely low.

In general, it will be appreciated by persons skilled in the art that numerous variations and/or modifications may be made to the above-described embodiments, without departing from the broad general scope of the present disclosure. The present embodiments are, therefore, to be considered in all respects as illustrative and not restrictive.

1. A solar cell comprising:
a semiconductor material and a dielectric layer located over a light-receiving surface of the semiconductor material;
a plurality of contacts, each contact of the plurality of contacts being a printed fire-through contact passing substantially through the dielectric layer, each contact of the plurality of contacts extending longitudinally in a first dimension; and
a conductive finger extending longitudinally in a second dimension substantially perpendicular to the first dimension and electrically connecting the plurality of contacts to first and second busbars at opposite ends of the conductive finger,
wherein the conductive finger has at least one first portion overlaying and electrically connecting to the plurality of contacts, wherein each of the plurality of contacts extends beyond the first portion of the conductive finger at one or both sides of the first portion of the conductive finger in the first dimension; and
wherein the first portion of the conductive finger overlays the dielectric layer and does not pass substantially through the dielectric layer.

2. The solar cell of claim 1, wherein the first portion of the conductive finger overlaying the dielectric layer is a non-fire-through portion of the conductive finger.

3. The solar cell of claim 1, wherein the plurality of contacts directly contact the semiconductor material or a conductive layer located between the semiconductor material and the dielectric layer.

4. The solar cell of claim 1, wherein the conductive finger has a higher conductivity at portions or regions of the conductive finger proximate the first and second bus bars, respectively, than at a central portion or region of the conductive finger between the first and second bus bars.

5. The solar cell of claim 4, wherein the portions or regions of the conductive finger proximate the first and second bus bars have higher conductivity than at the central portion of region of the conductive finger by comprising higher conductivity material, and/or by having a greater material thickness or width, than the central portion of region of the conductive finger.

6. The solar cell of claim 1, wherein the conductive finger comprises at least one second portion, the second portion of the conductive finger passing substantially through the dielectric layer.

7. The solar cell of claim 6, wherein the second portion of the conductive finger is a printed fire-through portion of the conductive finger.

8. The solar cell of claim 6 or 7, wherein the second portion of the conductive finger directly contacts the semiconductor material or a conductive layer located between the semiconductor material and the dielectric layer.

9. The solar cell of claim 8, wherein the second portion of the conductive finger:
does not overlay any of the plurality of contacts; or
overlays no more than one or two of the plurality of contacts; or
overlays no more than 10% of the total number of the plurality of contacts.

10. The solar cell of claim 6, wherein the second portion of the conductive finger comprises two second portions of the conductive finger, the two second portions of the conductive finger located at opposite ends of the first portion of the conductive finger and located proximate the first and second bus bars, respectively.

11. The solar cell of claim 10, wherein the second portion of the conductive finger has higher conductivity than the first portion of the conductive finger.

12. The solar cell of claim 6, wherein the first portion of the conductive finger comprises two first portions of the conductive finger, the two first portions of the conductive finger located at opposite ends of the second portion of the conductive finger and located proximate to the first and second bus bars, respectively.

13. The solar cell of claim 12, wherein the first portion of the conductive finger has higher conductivity than the second portion of the conductive finger.

14. The solar cell of claim 1, wherein the plurality of contacts are formed of silver and the first portion of the conductive finger is formed of a metal other than silver, or a metal alloy.

15. The solar cell of claim 14, wherein the first portion of the conductive finger is formed of aluminium, copper, tin, tin alloy or silver/aluminium alloy.

16. The solar cell of claim 6, wherein the second portion of the conductive finger is formed of silver, aluminium, copper, tin, tin alloy, or silver/aluminium alloy.

17. (canceled)

18. The solar cell of claim 1, when the solar cell comprises:
(i) the plurality of contacts,
(ii) the at least one first portion of the conductive finger,
(iii) the first and second busbars, and
optionally
(iv) at least one second portion of the conductive finger passing substantially through the dielectric layer, and
(v) at least one interconnection point, the first and/or second busbar being connected to the at least one interconnection point,
wherein any two or more of the items (i) to (v) are formed of a first metallic material and the remaining items of items (i) to (v) are formed of a second metallic material, the second metallic material being different from the first metallic material.

19. The solar cell of claim 1, wherein:
each contact of the plurality of contacts extends beyond the first portion of the conductive finger by at least 5 micrometres, at least 10 micrometres, at least 15 micrometres, at least 20 micrometres, or at least 25 micrometres, at one or both sides of the first portion of the conductive finger in the first dimension; and
wherein the first portion of the conductive finger has a width in the first dimension that is less than about 90%, 80%, 70%, 60%, or 50%, of a length of each contact of the plurality of contacts in the first dimension.

20-23. (canceled)

24. The solar cell of claim 1, wherein a metal/semiconductor material interface area of the solar cell at the light-receiving surface of the semiconductor material is between 0.5% and 2% of the total area of the light-receiving surface of the semiconductor material.

25. A method for fabricating a solar cell comprising:
depositing, on a dielectric layer that is over a light-receiving surface of a semiconductor material, a fire-through paste to define a plurality of contacts passing substantially through the dielectric layer, each contact of the plurality of contacts extending longitudinally in a first dimension; and
forming a conductive finger that extends longitudinally in a second dimension substantially perpendicular to the first dimension and electrically connects the plurality of contacts to first and second busbars at opposite ends of the conductive finger,
wherein forming the conductive finger comprises depositing non-fire-through paste to define at least a first portion of the conductive finger overlaying and electrically connecting to the plurality of contacts, wherein each contact of the plurality of contacts extends beyond the first portion of the conductive finger at one or both sides of the conductive finger in the first dimension; and
wherein the first portion of the conductive finger overlays the dielectric layer and does not pass substantially through the dielectric layer.

26. A solar cell comprising:
a semiconductor material and a dielectric layer located over a light-receiving surface of the semiconductor material;
a plurality of contacts, each contact of the plurality of contacts being a printed fire-through contact passing substantially through the dielectric layer, and
a conductive finger electrically connecting the plurality of contacts to first and second busbars at opposite ends of the conductive finger,
wherein the conductive finger has at least one first portion overlaying and electrically connecting to the plurality of contacts, the at least one first portion overlaying and not passing substantially through the dielectric layer; and
wherein the conductive finger comprises at least one second portion, the second portion of the conductive finger being a printed fire-through portion of the conductive finger passing substantially through the dielectric layer.

27. (canceled)

28. (canceled)
